(19) United States
(12) Patent Application Publication
(10) Pub. No.: US 2020/0287153 A1
(43) Pub. Date: Sep. 10, 2020

(54) SINGLE-DOPED WHITE OLEDS WITH EXTRACTION LAYER DOPED WITH DOWN-CONVERSION RED EMITTERS

(71) Applicant: Jian Li, Tempe, AZ (US)

(72) Inventor: Jian Li, Tempe, AZ (US)

(73) Assignee: Arizona Board of Regents on behalf of Arizona State University, Scottsdale, AZ (US)

(21) Appl. No.: 16/756,226

(22) PCT Filed: Oct. 17, 2018
(86) PCT No.: PCT/US18/56365

§ 371 Date: Apr. 15, 2020

Related U.S. Application Data
(60) Provisional application No. 62/573,462, filed on Oct. 17, 2017.

(51) Int. Cl. H01L 51/50; H01L 51/52

(52) U.S. Cl. CPC H01L 51/5036; H01L 51/5275; H01L 51/5268

(57) ABSTRACT

A white organic light emitting diode (OLED) having a substrate, a first electrode, a hole transporting layer proximate the first electrode, a second electrode, an electron transporting layer proximate the second electrode, an emissive layer between the hole transporting layer and the electron transporting layer, and a red-shifting layer optically coupled to the emissive layer. The red-shifting layer includes a red-shifting down-conversion emitter, and can be a scattering layer between the first electrode and the substrate, an C extraction layer optically coupled to the white OLED, or a microlens layer optically coupled to the white OLED.

### CROSS-REFERENCE TO RELATED APPLICATION

This application claims the benefit of U.S. Patent Application No. 62/573,462 filed Oct. 17, 2017.

### STATEMENT OF GOVERNMENT SUPPORT

This invention was made with government support under DE-EE0007090 awarded by the Department of Energy. The government has certain rights in the invention.

### TECHNICAL FIELD

This invention relates to single-doped white organic light emitting diodes (OLEDs) with an extraction layer doped with down-conversion red phosphors.

### BACKGROUND

FIG. 1 depicts a cross-sectional view of an OLED 100. OLED 100 includes anode 102, hole transporting layer (HTL) 104, emissive layer (EML) 106, electron transporting layer (ETL) 108, and metal cathode 110. Anode 102 is typically a transparent material, such as indium tin oxide, and may be formed on substrate 112. EML 106 may include an emitter and a host. Although phosphorescent emitters used in OLEDs such as OLED 100 can reach electron-to-photon conversion efficiency approaching 100%, much of the light emitted in these OLEDs remains trapped in the stratified thin film structure. FIG. 2 depicts four different pathways of photons (modes) in OLED 100, including plasmon mode 204, organic mode 206, and substrate mode 208, all of which represent trapping of photons in OLED 100, and air mode 210, which represents light emitted from OLED 100. Due at least in part to losses via plasmon mode 204, organic mode 206, and substrate mode 208, a maximum external quantum efficiency (EQE) of a typical OLED (e.g., 20-30%) is much less than that of a typical inorganic LED. Moreover, it is difficult to find phosphorescent excimers that can operate at high device efficiency and provide suitable monomer and excimer color.

### SUMMARY

In a general aspect, a white organic light emitting diode (OLED) includes a substrate, a first electrode, a hole transporting layer proximate the first electrode, a second electrode, an electron transporting layer proximate the second electrode, an emissive layer between the hole transporting layer and the electron transporting layer, and a red-shifting layer optically coupled to the emissive layer. The red-shifting layer includes a red-shifting down-conversion emitter.

Implementations of the general aspect may include one or more of the following features.

The red-shifting layer can be a scattering layer between the first electrode and the substrate, an extraction layer optically coupled to the white OLED, or a microlens layer optically coupled to the white OLED.

A concentration of the red-shifting down-conversion emitter in the red-shifting layer is typically in a range of 5 wt % to 100 wt %. The red-shifting layer can be a neat film or a composite film of the red-shifting down-conversion emitter. The red-shifting down-conversion emitter may be uniformly dispersed in the red-shifting layer.

The red-shifting down-conversion emitter may include one or more of an organic fluorescent dye, a quantum dot material, and a perovskite material. The quantum dot material typically includes one or more of a CdSe-based material and a InP-based material. The perovskite material typically includes one or more of CH₃NH₃PbBryI_{3-y} and CsPbBr_{y}I_{3-y}.

The red-shifting layer typically has a refractive index less than 1.5 or greater than 2. A thickness of the red-shifting layer is between 0.1 μm and 100 μm(e.g., between 10 μm and 50 μm). The red-shifting down-conversion emitter typically emits light having a wavelength in a range of 600 nm to 700 nm.

The details of one or more implementations of the subject matter described in this specification are set forth in the accompanying drawings and the description below. Other features, aspects, and advantages of the subject matter will become apparent from the description, the drawings, and the claims.

### BRIEF DESCRIPTION OF THE DRAWINGS

FIG. 1 depicts an organic light emitting diode (OLED).

FIG. 2 depicts different pathways of photons in an OLED.

FIG. 3 depicts an OLED-based lighting panel.

FIG. 4A shows an electroluminescent (EL) spectrum of a single-doped white OLED.

FIG. 4B shows an EL spectrum of a single-doped white OLED with a red photon enhanced extraction layer.

FIG. 5 shows simulated EL spectra of a single-doped white OLED with an enhanced extraction layer having varied red quantum-dot layer thickness.

FIG. 6 shows simulated EL spectra of a single-doped white OLED with an enhanced extraction layer having varied red KSF phosphor layer thickness.

FIG. 7 shows electroluminescent spectra of an OLED device, a similar OLED device with an external drop-cast KSF phosphor film, and another similar OLED device with an external drop-cast red quantum-dot film.

FIG. 8 shows photoluminescent spectra of an external drop-cast KSF phosphor film and an external drop-cast red quantum-dot film.

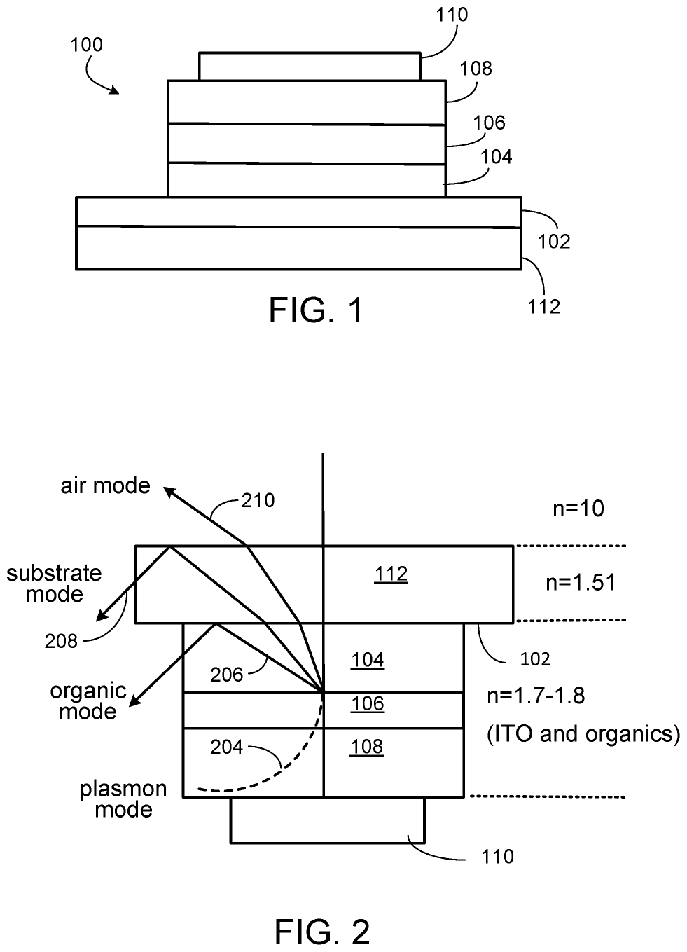

### DETAILED DESCRIPTION

As described herein, the device color of a single-doped white organic light emitting diodes (OLED) can be improved while increasing a light extraction efficiency of the OLED by including red-shifting down-conversion emitters in a light processing layer in or adjacent to a light emitting surface of a white OLED. Examples of suitable light processing layers include i) a scattering layer between electrode and substrate (an “internal” scattering layer) including a red-shifting down-conversion emitter; ii) an extraction layer optically coupled to a white OLED (an “external” extraction layer) including a red-shifting down-conversion emitter, and iii) a microlens layer optically coupled to the OLED including a red-shifting down-conversion emitter. The red-shifting down-conversion emitter emits photons having a wavelength in a range of 600 nm to 700 nm. As used herein, a “microlens layer” generally refers to a layer including multiple micro-size half-sphere lenses formed in a one- or two-dimensional array on a supporting substrate.

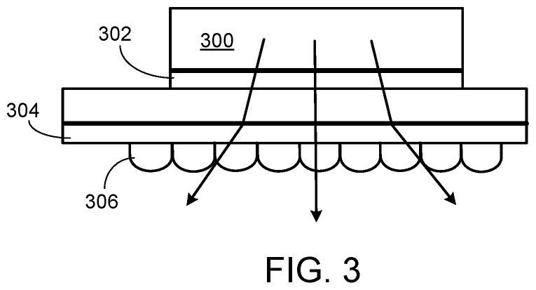

FIG. 3 depicts white OLED 300. In some embodiments, OLED 300 includes one or more of internal scattering layer 302, external extraction layer 304, and microlens layer 306. Internal scattering layer 302, external extraction layer 304, and microlens layer 306 can be a neat film or a doped film including a red-shifting down-conversion emitter, such as an appropriate organic fluorescent dye, a quantum dot material (e.g., CdSe- or InP-based material), or a perovskite material (e.g., CH₃NH₃PbBr_{y}I_{3-y} and CsPbBr_{y}I_{3-y}). A concentration of the down-converter in internal scattering layer 302, external extraction layer 304, or microlens layer 306 can be in a range of 5 wt % to 100 wt %. That is, internal scattering layer 302, external extraction layer 304, or microlens layer 306 can be a neat layer or a doped layer. The red-shifting down-conversion emitter is uniformly dispersed within the layer in which it is incorporated. Internal scattering layer 302, external extraction layer 304, and microlens layer 306 typically have a high refractive index (e.g., greater than 2) or a low refractive index (e.g., less than 1.5).

Internal scattering layer 302 may be formed between the anode and substrate of OLED 300 or between the cathode and substrate of OLED 300. Internal scattering layer 302 has a thickness in a range of 0.1 μm to 100 μm or 10 μm to 50 μm. In some embodiments, external extraction layer 304 is optically coupled to OLED 300. External extraction layer 304 may be formed on or optically coupled to an exterior surface of OLED 300, such as the exterior surface of the anode or cathode, or on an opposite surface of a substrate in direct contact with the anode or cathode. External extraction layer 304 has a thickness in a range of 0.1 μm to 100 μm or 10 μm to 50 μm. Microlens layer 306 is formed on or coupled to an exterior surface of OLED 300 through which light is emitted. Microlens features in microlens layer 306 can have a diameter in a range of 50 μm to 5000 μm.

The red-shifting down-conversion emitter in internal scattering layer 302, external extraction layer 304, or microlens layer 306 converts some of the blue and green photons emitted by the emissive layer in OLED 300 to red photons, resulting in a more ideal white spectrum with improved CIE (Commission Internationale de l'Eclairage) and CRI (Color Rendering Index) values.

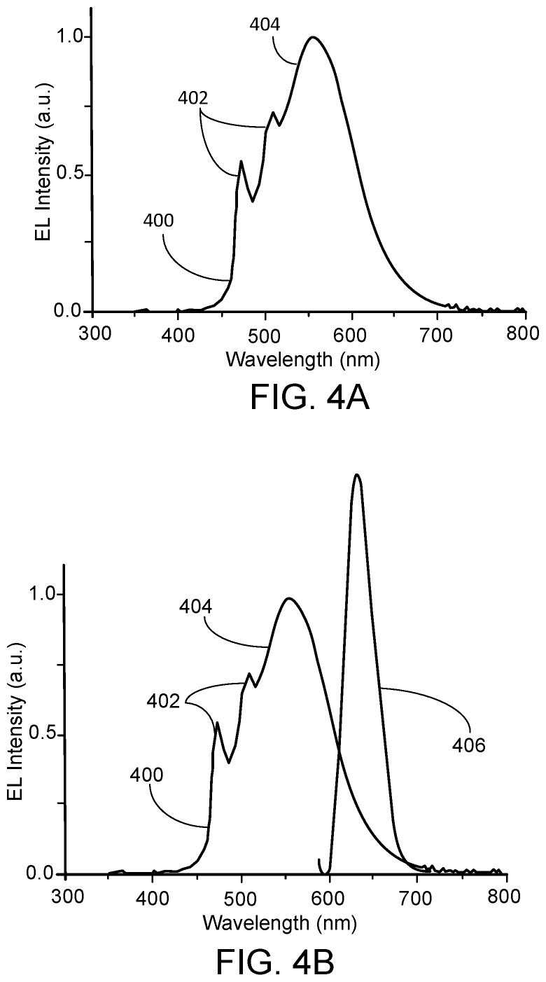

FIG. 4A shows electroluminescent (EL) spectrum 400 of a white OLED including Pd₃O₃ in the emissive layer.

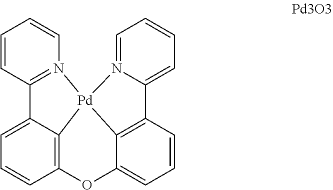

This OLED has a high device efficiency and balanced monomer emission 402 and excimer emission 404. However, the absence of deep red emission from the excimers affects the quality of white light (as evidenced by the CIE and CRI) emitted from the OLED. The addition of red-shifting down-conversion emitters in an internal scattering layer, an external extraction layer, or a microlens layer extracts more photons from the substrate mode and organic mode depicted in FIG. 2, and converts some of the blue and green photons to red photons, as depicted by red emission 406 in FIG. 4B.

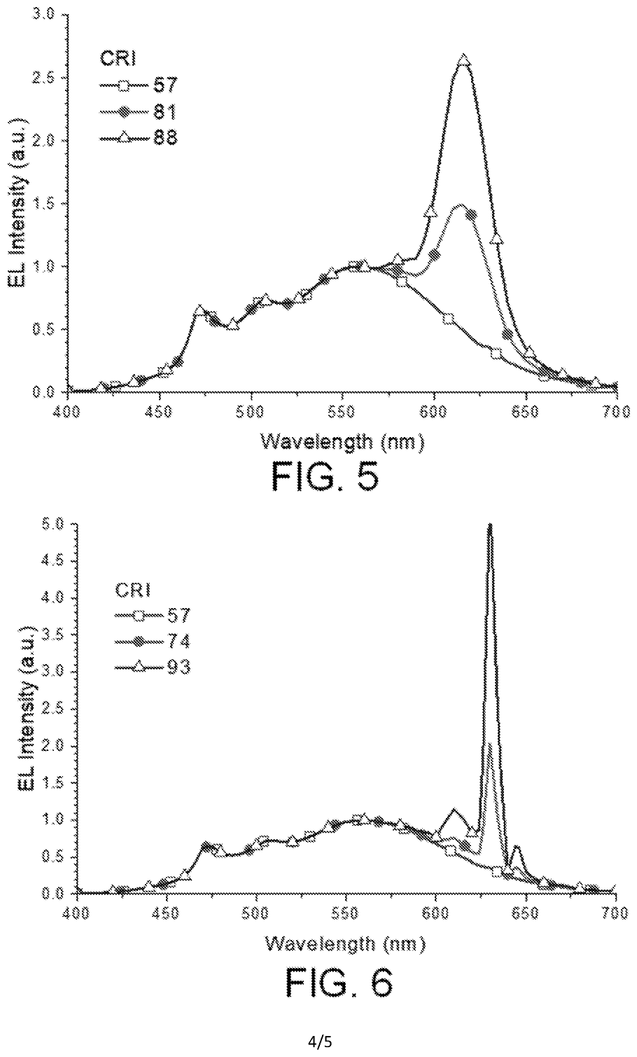

FIG. 5 shows simulated EL spectra of single-doped white OLEDs with and without a red quantum-dot enhanced extraction layer. The OLED color rendering index (CRI) values increase from 57 for an OLED without a red quantum-dot layer (open squares), to 81 for an OLED with a red quantum-dot layer of around 0.01-5 μm (solid circles), and to 88 for an OLED with a red quantum-dot layer of around 0.01-5 μm (open triangles).

FIG. 6 shows simulated EL spectra of single-doped white OLEDs with and without a red K₂SiF₆:Mn⁴⁺ (KSF) phosphor enhanced extraction layer. The CRI values increase from 57 for an OLED without a red KSF phosphor layer (open squares), to 74 for an OLED with a red KSF phosphor layer of intermediate thickness (solid circles), to 93 for an OLED with a red KSF phosphor layer of significant thickness (open triangles).

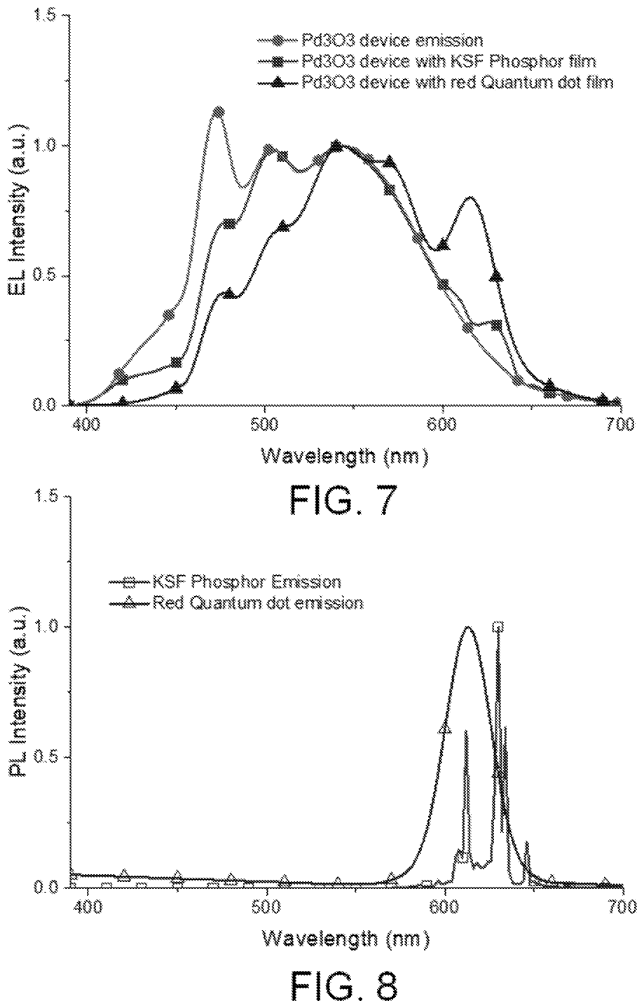

FIG. 7 shows electroluminescent spectra of an OLED device with a structure of ITO/HATCN (10 nm)/NPD (40 nm)/TrisPCz (10 nm)/6% Pd3O3:26mCPy (25 nm)/BAlq (10 nm)/BPyTP (40 nm)/LiQ/Al (solid circles), a similar Pd3O3-based OLED device with an external drop-cast red KSF phosphor film (solid squares), and a similar Pd3O3-based OLED device with an external drop-cast red quantum-dot film (solid triangles). In these OLEDs,

ITO: indium tin oxide

HATCN: hexaazatriphenylenehexacarbonitrile

NPD: N,N′-di(1-naphthyl)-N,N′-diphenyl-(1,1′-biphenyl)-4,4′-diamine

TrisPCz: (9,9′,9″-triphenyl-9H,9′H,9″H-3,3′:6′3″-tercarbazole)

26mCPy: 2,6-bis(N-carbazolyl) pyridine

BAlq: bis(8-hydroxy-2-methylquinoline)-(4-phenylphenoxy)aluminum

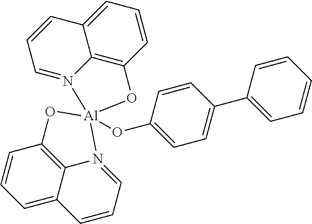

BPyTP: 2,7-di(2,2′-bipyridin-5-yl)triphenylene

LiQ: (8-hydroxyquinolinato)lithium

Al: aluminum

FIG. 8 shows photoluminescent spectra of an external drop-cast red KSF phosphor film (open squares) and an external drop-cast red quantum-dot film (open triangles).

Only a few implementations are described and illustrated. Variations, enhancements and improvements of the described implementations and other implementations can be made based on what is described and illustrated in this document.

What is claimed is:

1. A white organic light emitting diode comprising:
a substrate;
a first electrode;
a hole transporting layer proximate the first electrode;
a second electrode;
an electron transporting layer proximate the second electrode;
an emissive layer between the hole transporting layer and the electron transporting layer; and
a red-shifting layer optically coupled to the emissive layer, wherein the red-shifting layer comprises a red-shifting down-conversion emitter.

2. The white organic light emitting diode of claim 1, wherein the red-shifting layer comprises a scattering layer between the first electrode and the substrate.

3. The white organic light emitting diode of claim 1, wherein the red-shifting layer comprises an extraction layer optically coupled to the white organic light emitting diode.

4. The white organic light emitting diode of claim 1, wherein the red-shifting layer comprises a microlens layer optically coupled to the white organic light emitting diode.

5. The white organic light emitting diode of claim 1, wherein a concentration of the red-shifting down-conversion emitter in the red-shifting layer is in a range of 5 wt % to 100 wt %.

6. The white organic light emitting diode of claim 5, wherein the red-shifting layer comprises a neat film of the red-shifting down-conversion emitter.

7. The white organic light emitting diode of claim 5, wherein the red-shifting layer comprises a composite film comprising the red-shifting down-conversion emitter.

8. The white organic light emitting diode of claim 7, wherein the red-shifting down-conversion emitter is uniformly dispersed in the composite film.

9. The white organic light emitting diode of claim 1, wherein the red-shifting layer has a refractive index less than 1.5 or greater than 2.

10. The white organic light emitting diode of claim 1, wherein the red-shifting down-conversion emitter comprises one or more of an organic fluorescent dye, a quantum dot material, and a perovskite material.

11. The white organic light emitting diode of claim 10, wherein the red-shifting down-conversion emitter comprises an organic fluorescent dye.

12. The white organic light emitting diode of claim 10, wherein the red-shifting down-conversion emitter comprises a quantum dot material.

13. The white organic light emitting diode of claim 12, wherein the quantum dot material comprises one or more of a CdSe-based material and a InP-based material.

14. The white organic light emitting diode of claim 10, wherein the red-shifting down-conversion emitter comprises a perovskite material.

15. The white organic light emitting diode of claim 14, wherein the perovskite material comprises one or more of CH₃NH₃PbBr_{y}I_{3-y} and CsPbBr_{y}I_{3-y}.

16. The white organic light emitting diode of claim 1, wherein a thickness of the red-shifting layer is between 0.1 μm and 100 μm.

17. The white organic light emitting diode of claim 16, wherein a thickness of the red-shifting layer is between 10 μm and 50 μm.

18. The white organic light emitting diode of claim 1, wherein the red-shifting down-conversion emitter emits light having a wavelength in a range of 600 nm to 700 nm.
